(19) United States
(12) Patent Application Publication
(10) Pub. No.: US 2014/0300405 A1
(43) Pub. Date: Oct. 9, 2014

(54) INRUSH CURRENT CONTROL CIRCUIT

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: BO TIAN, Shenzhen (CN); KANG WU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/134,238

(22) Filed: Dec. 19, 2013

(30) Foreign Application Priority Data
Apr. 7, 2013 (CN) 2013101173925

(51) Int. Cl. H03K 17/284

(52) U.S. Cl. CPC H03K 17/284
USPC 327/399

(57) ABSTRACT

A control circuit includes a control module, a delay module, and an electronic switch. The control module is connected between a power supply and a load. The delay module is connected to the control module and the electronic switch. A first terminal of the electronic switch is connected to the control module and the delay module. A second terminal of the electronic switch is connected to the power supply. A third terminal of the electronic switch is connected to the load.

### BACKGROUND

1. Technical Field

The present disclosure relates to a control circuit for inrush current.

2. Description of Related Art

Inrush current is generated when an electronic device is turned on. A value of the inrush current is inversely proportional to a speed of turning on an electronic switch between a power source and the electronic device. If the inrush current is too high, the electronic device may be damaged.

Therefore, there is room for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a block diagram of an embodiment of a control circuit.

FIG. 2 is a circuit diagram of the control circuit of FIG. 1.

### DETAILED DESCRIPTION

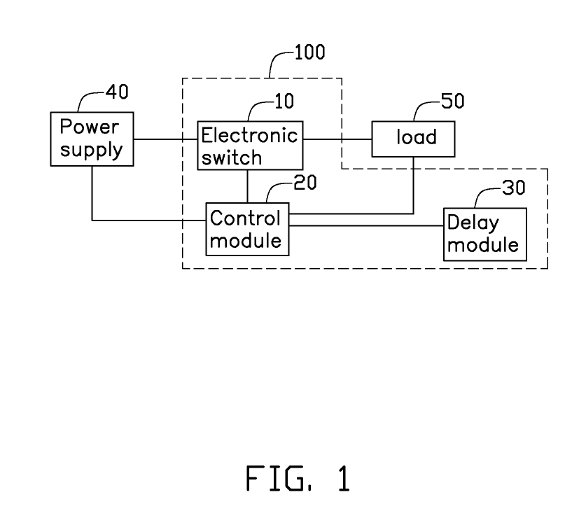

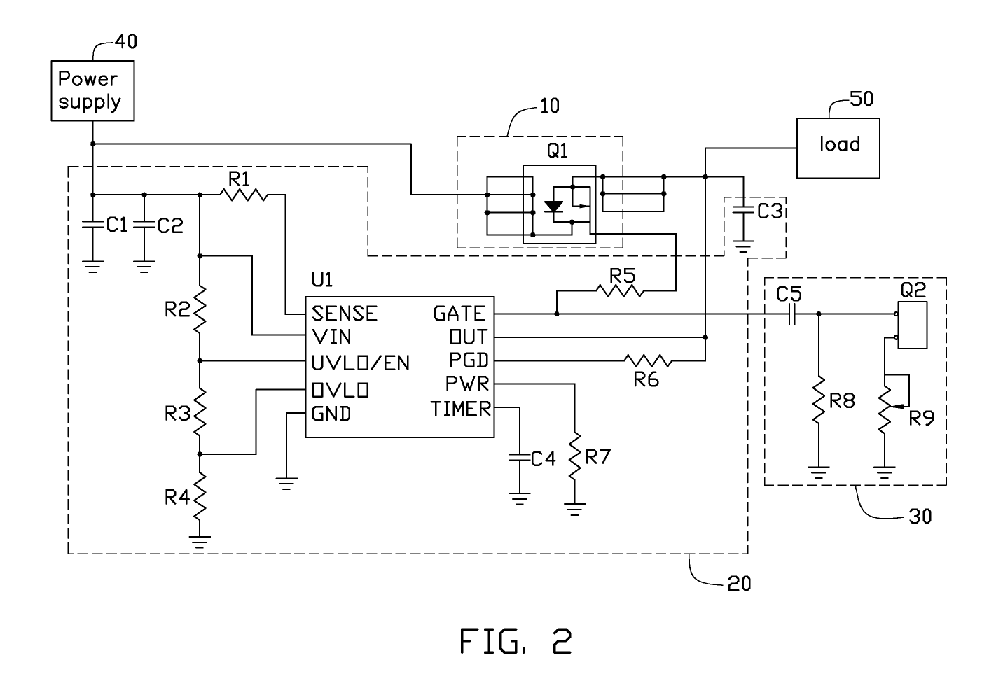

FIG. 1 and FIG. 2 show an embodiment of a control circuit 100.

The control circuit 100 is connected between a power supply 40 and a load 50. The control circuit 100 includes an electronic switch 10, a control module 20, and a delay module 30. A first terminal of the electronic switch 10 is connected to the control module 20. A second terminal of the electronic switch 10 is connected to the power supply 40. A third terminal of the electronic switch 10 is connected to the load 50. The delay module 30 delays a time that the control module 20 outputs a control signal to the electronic switch 10.

The control module 20 includes a control chip U1, resistors R1 to R7, and capacitors C1 to C4. The electronic switch 10 is an n-channel metal-oxide semiconductor field-effect transistor (MOSFET) Q1. A sensing pin of the control chip U1 is connected to the power supply 40 through the resistor R1. A node between the resistor R1 and the power supply 40 is grounded through the resistors R2, R3, and R4 in that order. The node between the resistor R1 and the power supply 40 is grounded through the capacitor C1. The capacitor C2 is connected to the capacitor C1 in parallel. A voltage pin VIN of the control chip U1 is connected to the node between the resistor R1 and the resistor R2. A comparing pin UVLO/EN of the control chip U1 is connected to a node between the resistor R2 and the resistor R3. A detecting pin UVLO of the control chip U1 is connected to a node between the resistor R3 and the resistor R4. A ground pin GND of the control chip U1 is grounded. A clock pin TIMER of the control chip U1 is grounded through the capacitor C4. Another ground pin PWR of the control chip U1 is grounded through the resistor R7. A power good pin PGD of the control chip U1 is grounded through the resistor R6 and the capacitor C3 in that order. An output pin OUT of the control chip U1 is connected to a node between the resistor R6 and the capacitor C3. A control pin GATE of the control chip U1 is connected to a gate of the MOSFET Q1 through the resistor R5.

A drain of the MOSFET Q1 is connected to the node between the power supply 40 and the resistor R1. A source of the MOSFET Q1 is connected to the node between the resistor R6 and the capacitor C3. A source of the MOSFET Q1 is also connected to the load 50.

The delay module 30 includes a resistor R8, a variable resistor R9, a capacitor C5, and a switch Q2. A first terminal of the switch Q2 is connected to the control pin GATE of the control chip U1 through the capacitor C5. The first terminal of the switch Q2 is grounded through the resistor R8. A second terminal of the switch Q2 is grounded through the variable resistor R9. When the switch Q2 is turned on, a parallel circuit of the resistors R8 and R9 is connected to the capacitor C5 in series as a delay circuit.

When the power supply 40 is powered on, the control module 20 receives a voltage from the power supply 40. When the voltage from the power supply 40 is consistent with a rated voltage of the load 50, a value of a difference between a first voltage received by the voltage pin VIN and a second voltage received by the comparing pin UVLO/EN is less than a preset value, the control chip U1 outputs a power good signal to the load 50, and the control chip U1 outputs a voltage through the control pin GATE to charge the capacitor C5. As the capacitor C5 is charged, a voltage of the capacitor C5 increases, until the voltage is enough to turn on the MOSFET Q1. Therefore, the load 50 starts to operate only when the load 50 receives both the power good signal and the voltage from the power supply 40. A time duration of this process is positively proportional to a resistance of the delay circuit. The resistance of the delay circuit can be increased by increasing the resistance of the variable resistor R9. Thus, the time duration of turning on the MOSFET Q1 is increased with the increasing of the resistance of the delay circuit. Therefore, the inrush current is decreased.

While the disclosure has been described by way of various embodiments, it is to be understood that the disclosure is not limited thereto. To the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A control circuit, comprising:
a control module connected between a power supply and a load;
a delay module connected to the control module to delay the control signal; and
an electronic switch, wherein when a voltage supplied by the power supply is consistent with a preset value, the control module outputs a power good signal to the load and a control signal simultaneously, a first terminal of the electronic switch is connected to the control module to receive the control signal delayed by the delay module, a second terminal of the electronic switch is connected to the power supply, a third terminal of the electronic switch is connected to the load, and the second terminal and the third terminal of the electronic switch are connected to each other when the first terminal receives the control signal delayed by the delay module.

2. The control circuit of claim 1, wherein the control module comprises a control chip, a first to seventh resistors, and a first to fourth capacitors, a sensing pin of the control chip is connected to the power supply through the first resistor, a node between the first resistor and the power supply is grounded through the second to fourth resistors in that order, the node between the first resistor and the power supply is grounded through the first capacitor, the second capacitor is connected to the first capacitor in parallel, a voltage pin of the control chip is connected to the node between the first resistor, the second resistor, and the power supply, a comparing pin of the control chip is connected to a node between the second resistor and the third resistor, a detecting pin of the control chip is connected to a node between the third resistor and the fourth resistor, a ground pin of the control chip is grounded, a clock pin of the control chip is grounded through the fourth capacitor, another ground pin of the control chip is grounded through the seventh resistor, a power good pin of the control chip is grounded through the sixth resistor and the third capacitor in that order, an output pin of the control chip is connected to a node between the sixth resistor and the third capacitor, a control pin of the control chip is connected to the first terminal of the electronic switch through the fifth resistor.

3. The control circuit of claim 2, wherein the delay module further comprises a fifth capacitor, an eighth resistor, a ninth resistor, and a switch, a first end of the fifth capacitor is connected to the control pin of the control chip, a second end of the fifth capacitor is grounded through the eighth resistor, and a series circuit of the switch and the ninth resistor is connected to the eighth resistor in parallel.

4. The control circuit of claim 2, wherein the second terminal of the electronic switch is connected to the node between the power supply and the first resistor.

5. The control circuit of claim 3, wherein the ninth resistor is a variable resistor.

6. The control circuit of claim 1, wherein the electronic switch is an n-channel metallic oxide semiconductor field effect transistor (MOSFET), the first terminal is a gate of the MOSFET, the second terminal is a drain of the MOSFET, and the third terminal is a source of the MOSFET.
